(19) United States
(12) Patent Application Publication
(10) Pub. No.: US 2026/0353944 A1
(43) Pub. Date: Nov. 5, 2026

(54) DISPLAY PANEL AND DISPLAY DEVICE

(71) Applicants: CHENGDU BOE OPTOELECTRONICS TECHNOLOGY CO., LTD., Sichuan (CN); BOE TECHNOLOGY GROUP CO., LTD., Beijing (CN)

(72) Inventors: Bo SHI, Beijing (CN); Ming HU, Beijing (CN); Gukhwan SONG, Beijing (CN); Yi ZHANG, Beijing (CN); Fengli JI, Beijing (CN); Jianji FU, Beijing (CN)

(21) Appl. No.: 19/116,422

(22) PCT Filed: Apr. 19, 2024
(86) PCT No.: PCT/CN2024/088878

§ 371 Date: Mar. 28, 2025

(30) Foreign Application Priority Data
May 30, 2023 (CN) 202310629010.0

(51) Int. Cl. H10K 59/126; H10K 59/121

(52) U.S. Cl. CPC H10K 59/126; H10K 59/1213

(57) ABSTRACT

A display panel and a display device, which belong to the technical field of display. The display panel includes a pixel circuit, including at least one target transistor. The display panel further includes: a substrate an active layer including a channel region of the target transistor, where the channel region of the target transistor includes at least one target channel region; a plurality of metal layers including a first metal layer, where the first metal layer includes a plurality of independent first metal blocks; and a plurality of light-shielding portions distributed in at least one of the plurality of metal layers, where the orthographic projection of the light-shielding portion on the base substrate is separate from the orthographic projection of the target channel region on the base substrate.

### CROSS-REFERENCE TO RELATED APPLICATIONS

This disclosure is the U.S. National phase application of International Application No. PCT/CN2024/088878, filed on Apr. 19, 2024, which claims priority to a Chinese patent application No. 202310629010.0, filed on May 30, 2023, and entitled “DISPLAY PANEL AND DISPLAY APPARATUS,” the entire contents of which are incorporated herein by reference in their entireties.

### TECHNICAL FIELD

This disclosure relates to the field of display technology, and in particular, to a display panel and a display device.

### BACKGROUND

In the prior art, Organic Light Emitting Diode (OLED) display panels may experience color deviation in white state displays, such as a pink-tinted phenomenon, when activated under wide-angle, high-intensity ambient lighting conditions.

The above-disclosed information in the “BACKGROUND” section is only used to enhance the understanding of the background of this disclosure. Therefore, it may include information that does not constitute prior art known to those of ordinary skill in the art.

### SUMMARY

The objective of this disclosure is to provide a display panel and a display device to improve the pink-tinted phenomenon of the display panel in the white state displays.

To achieve the above-mentioned objective, this disclosure adopts the following technical solutions.

According to a first aspect of this disclosure, a display panel is provided. The display panel includes a pixel circuit, and the pixel circuit includes at least one target transistor. The display panel further includes:
a substrate;
an active layer, on a side of the substrate, including an active portion of the target transistor, the active portion of the target transistor including a channel region, the channel region of the target transistor including at least one target channel region;
a plurality of metal layers, on a side of the active layer away from the substrate, including a first metal layer, the first metal layer including a plurality of independent first metal blocks; and
a plurality of light-shielding portions distributed in at least one metal layer of the plurality of metal layers, an orthographic projection of the light-shielding portion on the substrate being separated from an orthographic projection of the first metal block on the substrate; wherein
the first metal block has a plurality of edges connected end to end, the plurality of edges of the first metal block including at least one target edge;
an orthographic projection of the active portion of the target transistor on the substrate at least partially overlaps with an orthographic projection of the corresponding first metal block on the substrate;
a distance, between the target channel region of the target transistor and the target edge of the corresponding first metal block, in a direction parallel to the substrate, is less than or equal to a distance, between the target channel region of the target transistor and an other edge of the corresponding first metal block, in the direction parallel to the substrate; and
a distance, between the target edge and at least one of the plurality of light-shielding portions, is greater than or equal to Oum.

In an exemplary embodiment of this disclosure, the orthographic projection of the light-shielding portion on the substrate surrounds the orthographic projection of the first metal block on the substrate.

In an exemplary embodiment of this disclosure, an orthographic projection of the target channel region of the target transistor on the corresponding first metal block is a first projection, and an orthographic projection of the first projection on the target edge of the corresponding first metal block is a second projection; and
an orthographic projection of the light-shielding portion on the first metal layer is a third projection, and a projection of the third projection on the target edge of the corresponding first metal block is a fourth projection, the second projection being located within the fourth projection.

In an exemplary embodiment of this disclosure, the display panel further includes:
a first insulating layer on a side of the active layer away from the substrate, the light-shielding portion being on a surface of the first insulating layer on a side away from the substrate;
wherein the surface of the first insulating layer on the side away from the substrate is provided with a plurality of protrusions or grooves, and the light-shielding portion at least covers a surface of the protrusion or the groove.

In an exemplary embodiment of this disclosure, the protrusion has a bottom end close to the substrate, a top end away from the substrate, and a side wall connecting the bottom end and the top end, and an orthographic projection of the top end of the protrusion on the substrate is located within an orthographic projection of the bottom end of the protrusion on the substrate.

In an exemplary embodiment of this disclosure, an angle, between the side wall of the protrusion and a plane where the substrate is located, ranges from 25° to 70°.

In an exemplary embodiment of this disclosure, the groove has a bottom end close to the substrate, a top end away from the substrate, and a side wall connecting the bottom end and the top end, and an orthographic projection of the bottom end of the groove on the substrate is located within an orthographic projection of the top end of the groove on the substrate.

In an exemplary embodiment of this disclosure, an angle, between the side wall of the groove and a plane where the substrate is located, ranges from 25° to 70°.

In an exemplary embodiment of this disclosure, a height of the protrusion ranges from 0.5 μm to 2 μm; and a depth of the groove ranges from 0.5 μm to 2 μm.

In an exemplary embodiment of this disclosure, the display panel further includes:
a first gate insulating layer on the side of the active layer away from the substrate;
a first gate metal layer, on a side of the first gate insulating layer away from the substrate, including a gate of the target transistor;
a second gate insulating layer on a side of the first gate metal layer away from the substrate;
a second gate metal layer on a side of the second gate insulating layer away from the substrate;
an inter-layer dielectric layer on a side of the second gate metal layer away from the substrate;
a first source-drain metal layer, on a side of the inter-layer dielectric layer away from the substrate, including a source and a drain of the target transistor;
a first planarization layer on a side of the first source-drain metal layer away from the substrate;
a second source-drain metal layer on a side of the first planarization layer away from the substrate; and
a second planarization layer on a side of the second source-drain metal layer away from the substrate, wherein the first metal layer is on a side of the second planarization layer away from the substrate;
wherein the plurality of metal layers further include the first gate metal layer, the second gate metal layer, the first source-drain metal layer, and the second source-drain metal layer;
when the plurality of light-shielding portions are distributed in the first gate metal layer, the first gate insulating layer serves are the first insulating layer;
when the plurality of light-shielding portions are distributed in the second gate metal layer, the second gate insulating layer serves as the first insulating layer;
when the plurality of light-shielding portions are distributed in the first source-drain metal layer, the inter-layer dielectric layer serves as the first insulating layer;
when the plurality of light-shielding portions are distributed in the second source-drain metal layer, the first planarization layer serves as the first insulating layer;
when the plurality of light-shielding portion are distributed in the first metal layer, the second planarization layer serves as the first insulating layer.

In an exemplary embodiment of this disclosure, the at least one target channel region includes a first target channel region;
the at least one target edge includes a first target edge;
a distance, between the first target channel region of the target transistor and the first target edge of the corresponding first metal block, in the direction parallel to the substrate, is less than a distance, between the first target channel region of the target transistor and an other edge of the corresponding first metal block except the target edge, in the direction parallel to the substrate; and
the plurality of light-shielding portions include a first light-shielding portion on a side, away from the first target channel region, of the first target edge in the direction parallel to the substrate.

In an exemplary embodiment of this disclosure, the at least one target edge further includes a second target edge connected to the first target edge, with an angle between the first target edge and the second target edge;
a distance, between the first target channel region of the target transistor and the second target edge of the corresponding first metal block, in the direction parallel to the substrate, is less than a distance, between the first target channel region of the target transistor and an other edge of the corresponding first metal block except the target edge, in the direction parallel to the substrate; and
the plurality of light-shielding portion further include a second light-shielding portion on a side, away from the first target channel region, of the second target edge in the direction parallel to the substrate, the second light-shielding portion being connected to the first light-shielding portion.

In an exemplary embodiment of this disclosure, the at least one target edge further includes a third target edge, with the first target edge, the second target edge, and the third target edge connected in sequence, and an angle between the second target edge and the third target edge;
a distance, between the first target channel region of the target transistor and the third target edge of the corresponding first metal block, in the direction parallel to the substrate, is less than a distance, between the first target channel region of the target transistor and an other edge of the corresponding first metal block except the target edge, in the direction parallel to the substrate; and
the plurality of light-shielding portions further include a third light-shielding portion on a side, away from the first target channel region, of the third target edge in the direction parallel to the substrate, the first light-shielding portion, the second light-shielding portion, and the third light-shielding portion being connected in sequence.

In an exemplary embodiment of this disclosure, the at least one target channel region further includes a second target channel region;
the at least one target edge further includes a fourth target edge connected to the first target edge, with an angle between the fourth target edge and the first target edge;
a distance, between the second target channel region of the target transistor and the fourth target edge of the corresponding first metal block in the direction parallel to the substrate, is less than a distance, between the second target channel region of the target transistor and an other edge of the corresponding first metal block except the target edge, in the direction parallel to the substrate; and
the plurality of light-shielding portions further include a fourth light-shielding portion on a side, away from the second target channel region, of the fourth target edge in the direction parallel to the substrate, the fourth light-shielding portion being connected to the first light-shielding portion.

In an exemplary embodiment of this disclosure, the orthographic projection of the light-shielding portion on the substrate is a bent strip-shaped structure, and a width of the bent strip-shaped structure ranges from 2 μm to 5 μm.

In an exemplary embodiment of this disclosure, the display panel further includes:
a first source-drain metal layer, on the side of the active layer away from the substrate, including a source and a drain of the target transistor;
a first planarization layer on a side of the first source-drain metal layer away from the substrate;
a second source-drain metal layer on a side of the first planarization layer away from the substrate; and
a second planarization layer on a side of the second source-drain metal layer away from the substrate, wherein the first metal layer is on a side of the second planarization layer away from the substrate;
wherein the plurality of metal layers include the first source-drain metal layer, the second source-drain metal layer, and the first metal layer; and
at least a portion of the plurality of light-shielding portions are distributed in the first metal layer and/or the second source-drain metal layer.

In an exemplary embodiment of this disclosure, the orthographic projection of the light-shielding portion on the substrate surrounds the orthographic projection of the first metal block on the substrate; and
a distance, between the light-shielding portion distributed in the first metal layer and the first metal block surrounded by the light-shielding portion, ranges from 2 μm to 5 μm.

In an exemplary embodiment of this disclosure, a connection portion is connected between the light-shielding portion distributed in the first metal layer and the first metal block surrounded by the light-shielding portion, and the connection portion is distributed in the first metal layer.

In an exemplary embodiment of this disclosure, a distance, between the target channel region and the target edge, in the direction parallel to the substrate, is less than or equal to 5 μm.

In an exemplary embodiment of this disclosure, the pixel circuit includes a driving transistor; and a second transistor, a first electrode of the second transistor being connected to a first electrode of the driving transistor, a second electrode of the second transistor being connected to a gate of the driving transistor, and a gate of the second transistor being connected to a gate driving signal terminal; and
wherein the second transistor serves as the target transistor.

In an exemplary embodiment of this disclosure, the second transistor is a dual-channel transistor.

In an exemplary embodiment of this disclosure, the pixel circuit further includes:
a first transistor, with a first electrode connected to a first node, a second electrode connected to an initial signal terminal, and a gate connected to a reset signal terminal;
a fourth transistor, a first electrode of the fourth transistor being connected to a data signal terminal, a second electrode of the fourth transistor being connected to a second electrode of the driving transistor, and a gate of the fourth transistor being connected to the gate driving signal terminal;
a fifth transistor, a first electrode of the fifth transistor being connected to a first power supply terminal, a second electrode of the fifth transistor being connected to the second electrode of the driving transistor, and a gate of the fifth transistor being connected to an enable signal terminal;
a sixth transistor, a first electrode of the sixth transistor being connected to the first electrode of the driving transistor, and a gate of the sixth transistor being connected to the enable signal terminal;
a seventh transistor, a first electrode of the seventh transistor being connected to the initial signal terminal, a second electrode of the seventh transistor being connected to a second electrode of the sixth transistor, and a gate of the seventh transistor being connected to the reset signal terminal; and
a capacitor connected between the gate of the driving transistor and the first power supply terminal;
wherein the first electrode of the second transistor is connected to the first electrode of the driving transistor, the second electrode of the second transistor is connected to the first node, the gate of the second transistor is connected to the gate driving signal terminal, and the gate of driving transistor is connected to the first node.

In an exemplary embodiment of this disclosure, a distance, between the orthographic projection of the light-shielding portion on the substrate and the orthographic projection of the first metal block surrounded by the light-shielding portion on the substrate, ranges from Oum to 5 μm.

According to a second aspect of this disclosure, a display device is further provided. The display device includes the display panel as described in the first aspect.

### BRIEF DESCRIPTION OF THE DRAWINGS

The foregoing and other features and advantages of this disclosure will become more apparent by describing in detail exemplary embodiments thereof with reference to the accompanying drawings.

FIG. 1 is an equivalent schematic diagram of a pixel circuit of a display panel according to exemplary embodiments of this disclosure.

FIG. 2 is a schematic diagram of a film-layer structure of a display panel according to exemplary embodiments of this disclosure.

FIG. 3 is a schematic diagram of a film-layer structure of a display panel according to exemplary embodiments of this disclosure.

FIG. 4 is a structural schematic diagram for a process of forming a light-shielding portion according to exemplary embodiments of this disclosure.

FIG. 5 is a schematic diagram of a film-layer structure of a display panel according to exemplary embodiments of this disclosure.

FIG. 6 is a schematic diagram of a film-layer structure of a display panel according to exemplary embodiments of this disclosure.

FIG. 7 is a schematic diagram of a film-layer structure of a display panel according to exemplary embodiments of this disclosure.

FIG. 8 is a schematic diagram of a film-layer structure of a display panel according to exemplary embodiments of this disclosure.

FIG. 9 is a schematic diagram of a film-layer structure of a display panel according to exemplary embodiments of this disclosure.

FIG. 10 is a schematic diagram of a film-layer structure of a display panel according to exemplary embodiments of this disclosure.

FIG. 11 is a schematic diagram of a principle of reducing an aperture ratio loss by setting protrusions according to exemplary embodiments of this disclosure.

FIG. 12 is an exemplary layout of an active layer according to exemplary embodiments of this disclosure.

FIG. 13 is an exemplary layout of a first gate metal layer according to exemplary embodiments of this disclosure.

FIG. 14 is a schematic diagram of the superimposition of FIG. 12 and FIG. 13 according to exemplary embodiments of this disclosure.

FIG. 15 is an exemplary layout of a first metal layer according to an exemplary embodiment of this disclosure.

FIG. 16 is a schematic diagram of the superimposition of FIG. 12, FIG. 13, and FIG. 15 according to exemplary embodiments of this disclosure.

FIGS. 17 and 18 are schematic diagrams of structures of the light-shielding portion according to exemplary embodiments of this disclosure.

FIG. 19 is an exemplary layout of a second source-drain metal layer according to exemplary embodiments of this disclosure.

FIG. 20 is an exemplary layout of a first metal layer according to another exemplary embodiment of this disclosure.

FIG. 21 is an exemplary layout of a first metal layer according to yet another exemplary embodiment of this disclosure.

FIG. 22 is an exemplary layout of a second gate metal layer according to exemplary embodiments of this disclosure.

FIG. 23 is an exemplary layout of a first source-drain metal layer according to exemplary embodiments of this disclosure.

FIG. 24 is another exemplary layout of a second source-drain metal layer according to exemplary embodiments of this disclosure.

FIG. 25 is a schematic diagram of the superimposition of the layouts of FIGS. 12, 13, 22, 23, 24, and 15 according to exemplary embodiments of this disclosure.

FIG. 26 is a cross-sectional view at the position A-A in FIG. 25.

FIG. 27 is a schematic diagram of the superimposition of FIGS. 12, 13, and 19 according to exemplary embodiments of this disclosure.

FIG. 28 is a schematic diagram of the superimposition of an active layer, a first gate metal layer, and a first metal layer according to another exemplary embodiment of this disclosure.

Reference numerals of main components in the figures are explained as follows.

100—substrate; 201—shielding layer; 202—buffer layer; 203—active layer; 204—first gate insulating layer; 205—first gate metal layer; 206—second gate insulating layer; 207—second gate metal layer; 208—inter-layer dielectric layer; 209—first source-drain metal layer; 210—passivation layer; 211—first planarization layer; 212—second source-drain metal layer; 213—second planarization layer; 301—protrusion; 302—groove; 400—light-shielding portion; 401—first light-shielding portion; 402—second light-shielding portion; 403—third light-shielding portion; 404—fourth light-shielding portion; 500—first metal layer; 501—first metal block; 5011—first target edge; 5012—second target edge; 5013—third target edge; 5014—fourth target edge; 5015—connection portion; 502—light-emitting device; 503—pixel definition layer; 600—encapsulation layer; 10-—target channel region; 11—first target channel region; 12—second target channel region.

### DETAILED DESCRIPTION

The exemplary embodiments will now be described more comprehensively with reference to the accompanying drawings. However, the exemplary embodiments can be implemented in various forms and should not be construed as being limited to the examples set forth herein. On the contrary, these embodiments are provided so that this disclosure will be more thorough and complete, and the concept of the exemplary embodiments will be fully conveyed to those skilled in the art. The described features, structures, or characteristics can be combined in any suitable manner in one or more embodiments. In the following description, numerous specific details are provided to give a full understanding of the embodiments of this disclosure.

In the figures, the thicknesses of regions and layers may be exaggerated for clarity. The same reference numerals in the figures denote the same or similar structures, and thus their detailed descriptions will be omitted.

The described features, structures, or characteristics can be combined in any suitable manner in one or more embodiments. In the following description, numerous specific details are provided to give a full understanding of the embodiments of this disclosure. However, those skilled in the art will realize that the technical solutions of this disclosure can be practiced without one or more of the specific details, or other methods, components, materials, etc. can be used. In other cases, well-known structures, materials, or operations are not shown or described in detail to avoid obscuring the main technical concept of this disclosure.

When a structure is “on” another structure, it may mean that the structure is integrally formed on the other structure, or that the structure is “directly” disposed on the other structure, or that the structure is “indirectly” disposed on the other structure through another structure.

The terms “a”, “an”, and “the” are used to indicate the existence of one or more elements/components/etc. The terms “comprising” and “having” are used to express an open-ended inclusion meaning and mean that in addition to the listed elements/components/etc., there may also be other elements/components/etc. The terms “first” and “second”, etc. are only used as labels and are not limitations on the number of objects to which they refer.

In the related art, OLED display panels experience a pink-tinted phenomenon in white state displays when activated under wide-angle, high-intensity ambient lighting conditions.

In the related art, an OLED display panel includes a substrate, a driving circuit layer disposed on a side of the substrate, and a light-emitting device layer disposed on a side of the driving circuit layer away from the substrate. The driving circuit layer includes a plurality of pixel circuits, the light-emitting device layer includes a plurality of light-emitting devices, and the pixel circuits are provided in one-to-one correspondence with the light-emitting devices to drive each light-emitting device to emit light. The driving circuit layer is a multi-layer film stacked structure, including a metal shielding layer and an active layer disposed on a side of the metal shielding layer away from the substrate. The active layer includes the channel regions of the transistors in the pixel circuits.

Through simulation, it is found that under wide-angle, high-intensity ambient lighting conditions, the high-intensity light is reflected by the metal shielding layer and irradiated into the channel regions of the transistors in the pixel circuits, causing changes in characteristics of the transistors, thereby affecting the light-emitting characteristics of the corresponding light-emitting devices and resulting in a pink-tinted phenomenon in white state displays of the display panel.

This disclosure provides a display panel. The display panel includes a pixel circuit, and the pixel circuit includes at least one target transistor. The display panel further includes: a substrate 100; an active layer 203 disposed on a side of the substrate 100, where the active layer 203 includes an active portion of the target transistor, the active portion of the target transistor includes a channel region, and the channel region of the target transistor includes at least one target channel region 10; a plurality of metal layers disposed on a side of the active layer 203 away from the substrate 100, where the plurality of metal layers include a first metal layer 500, and the first metal layer 500 includes a plurality of independent first metal blocks 501; a plurality of light-shielding portions 400 distributed in at least one metal layer of the plurality of metal layers, where an orthographic projection of the light-shielding portion 400 on the substrate 100 is separated from an orthographic projection of the first metal block 501 on the substrate 100. The first metal block 501 has a plurality of edges, the plurality of edges of the first metal block 501 are connected end to end, and the plurality of edges of the first metal block 501 include at least one target edge. An orthographic projection of the active portion of the target transistor on the substrate 100 at least partially overlaps with the orthographic projection of the corresponding first metal block 501 on the substrate 100. And a distance, between the target channel region 10 of the target transistor and the target edge of the corresponding first metal block 501, in a direction parallel to the substrate 100 is not greater than, such as less than or equal to, a distance between the target channel region 10 of the target transistor and the other edge of the corresponding first metal block 501 in the direction parallel to the substrate 100. At least one light-shielding portion 400 is located at the position of the target edge.

The display panel provided by this disclosure includes the substrate 100, the active layer 203, and the plurality of metal layers. The plurality of metal layers is disposed on the side of the active layer 203 away from the substrate 100. The display panel further includes light-shielding portions 400, and the light-shielding portions 400 are distributed in at least one metal layer of the plurality of metal layers. The plurality of metal layers include the first metal layer 500, and the first metal layer 500 includes the plurality of independent first metal blocks 501. The display panel includes the pixel circuit, and the pixel circuit includes at least one target transistor. The channel region of the target transistor includes at least one target channel region 10. The first metal block 501 has a target edge. At least one light-shielding portion 400 is located at the position of the target edge. In this setting, the light-shielding portion 400 can block a portion of the light under wide-angle illumination, reducing the amount of light incident on the target channel region 10, thereby avoiding changes in characteristics of the transistor, and further improving the pink-tinted phenomenon in white state displays of the display panel.

The following will describe in detail each component of the display panel provided by this disclosure with reference to the accompanying drawings and specific embodiments.

The display panel provided by this disclosure can be an Organic Light-Emitting Diode (OLED) display panel, etc. The display panel includes a pixel circuit, and the pixel circuit includes at least one target transistor. The pixel circuit can be an nTmC pixel circuit, where nTmC means that a pixel circuit includes n transistors (represented by the letter “T”) and m capacitors (represented by the letter “C”). For example, the pixel circuit can be a 7T1C, 7T2C, 6T1C, or 6T2C pixel circuit.

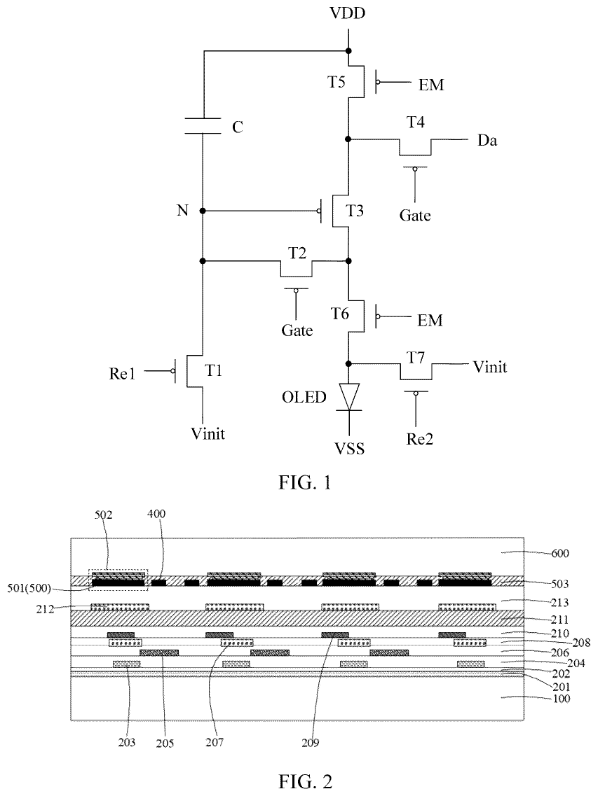

As shown in FIG. 1, in some embodiments of this disclosure, the pixel circuit is a 7T1C pixel circuit. The pixel circuit includes a first transistor T1, a second transistor T2, a driving transistor T3, a fourth transistor T4, a fifth transistor T5, a sixth transistor T6, a seventh transistor T7, and a capacitor C. A first electrode of the first transistor T1 is connected to node N, a second electrode of the first transistor T1 is connected to an initial signal terminal Vinit, and a gate is connected to a reset signal terminal Rel. A first electrode of the second transistor T2 is connected to a first electrode of the driving transistor T3, a second electrode of the second transistor T2 is connected to node N, and a gate of the second transistor T2 is connected to a gate driving signal terminal Gate. A gate of the driving transistor T3 is connected to node N. A first electrode of the fourth transistor T4 is connected to a data signal terminal Da, a second electrode of the fourth transistor T4 is connected to a second electrode of the driving transistor T3, and a gate of the fourth transistor T4 is connected to the gate driving signal terminal Gate. A first electrode of the fifth transistor T5 is connected to a first power supply terminal VDD, a second electrode of the fifth transistor T5 is connected to the second electrode of the driving transistor T3, and a gate of the fifth transistor T5 is connected to an enable signal terminal EM. A first electrode of the sixth transistor T6 is connected to the first electrode of the driving transistor T3, and a gate of the sixth transistor T6 is connected to the enable signal terminal EM. A first electrode of the seventh transistor T7 is connected to the initial signal terminal Vinit, a second electrode of the seventh transistor T7 is connected to a second electrode of the sixth transistor T6, and a gate of the seventh transistor T7 is connected to a reset signal terminal Re2. The capacitor C is connected between the gate of the driving transistor T3 and the first power supply terminal VDD. This pixel driving circuit can be connected to a light-emitting device OLED to drive the light-emitting device OLED to emit light. The light-emitting device OLED can be connected between the second electrode of the sixth transistor T6 and a second power supply terminal VSS. The transistors T1-T7 can all be P-type transistors.

It should be noted that the transistors used in all embodiments of this disclosure can be thin-film transistors, field-effect transistors, or other devices with the same characteristics. In this specification, the first electrode can be a drain electrode, the second electrode can be a source electrode, or the first electrode can be a source electrode, and the second electrode can be a drain electrode.

As shown in FIG. 2, the display panel further includes a substrate 100, an active layer 203, a plurality of metal layers, and a plurality of light-shielding portions 400.

The substrate 100 can be made of glass materials such as soda-lime glass, quartz glass, sapphire glass, or metal materials such as stainless steel, aluminum, nickel, etc. The substrate 100 can also be a flexible substrate 100. For example, in an embodiment of this disclosure, the material of the substrate 100 can be polyimide (PI). The substrate 100 can also be a composite of multiple materials. For example, in an embodiment of this disclosure, the substrate 100 can include a bottom film layer, a pressure-sensitive adhesive layer, a first polyimide layer, and a second polyimide layer that are stacked in sequence.

As shown in FIGS. 2, 12, 14, and 16-18, the active layer 203 is disposed on a side of the substrate 100. The active layer 203 includes an active portion of a target transistor. The active portion of the target transistor includes a channel region, and the channel region of the target transistor includes at least one target channel region 10. The target transistor can be any transistor included in the pixel circuit. For example, in a 7T1C pixel circuit, the target transistor can be any one or more of the first transistor T1, the second transistor T2, the driving transistor T3, the fourth transistor T4, the fifth transistor T5, the sixth transistor T6, and the seventh transistor T7.

The target transistor includes at least one target channel region 10. In this disclosure, the target transistor can include one, two, or more channel regions. Among these channel regions, one, two, or more channel regions can be target channel regions 10. The target transistor can be a dual-channel transistor.

In some embodiments of this disclosure, the active layer 203 includes the channel regions of the first transistor T1, the second transistor T2, the driving transistor T3, the fourth transistor T4, the fifth transistor T5, the sixth transistor T6, and the seventh transistor T7. The number of channel regions included in different transistors can be different. The first transistor T1 and the second transistor T2 can be dual-channel transistors, that is, they include two channel regions. The specific positions of the channel regions in each transistor are not particularly limited in this disclosure. In a specific embodiment, the layout of the active layer 203 is as shown in FIG. 12. The positions of the channel regions of each transistor are exemplarily marked in the figure, but this distribution position is only an exemplary illustration and does not particularly limit this disclosure. In some embodiments of this disclosure, the target transistor can be a dual-channel transistor. That is, the target transistor can include the first transistor T1 and the second transistor T2.

The plurality of metal layers are disposed on a side of the active layer 203 away from the substrate 100. The plurality of metal layer include a first metal layer 500. The first metal layer 500 includes a plurality of independent first metal blocks 501. An orthographic projection of the first metal block 501 on the substrate 100 can be in various shapes, such as a polygon with rounded corners or an irregular closed figure, etc. The shapes of the plurality of first metal blocks 501 can be different from each other. The first metal block 501 can be used as the anode of the light-emitting device 502.

In some embodiments of this disclosure, the light-emitting device 502 further includes a light-emitting functional layer and a second electrode layer. The light-emitting functional layer can include a hole-injection layer, a hole-transport layer, a light-emitting material layer, an electron-transport layer, and an electron-injection layer that are sequentially stacked in a direction away from the substrate 100. Visible light can be generated by the recombination of holes and electrons into excitons in the light-emitting material layer and the radiation of photons by the excitons. The specific light-emitting principle will not be described in detail here. The second electrode layer can cover the light-emitting functional layer and can be used as the cathode of the light-emitting device 502. The second electrode layer can be a single-layer or multi-layer structure, and its material can include one or more of conductive metals, metal oxides, and alloys.

The display panel further includes a pixel definition layer 503. The pixel definition layer 503 can be disposed on a side of the first metal layer 500 away from the substrate 100. The pixel definition layer 503 is used to separate the light-emitting devices 502. Specifically, the pixel definition layer 503 can be provided with a plurality of openings, and the range defined by each opening is the range of a light-emitting device 502. The shape of the opening, that is, the contour of the orthographic projection of the opening on the substrate 100, can be a polygon, a smooth closed curve, or other shapes. The smooth closed curve can be a circle, an ellipse, or a waisted oval, etc., and is not particularly limited here. The light-emitting functional layer is located within the opening of the pixel definition layer 503.

The display panel further includes an encapsulation layer 600. The encapsulation layer 600 covers the surface of the second electrode layer away from the substrate 100 and can be used to block the erosion of water and oxygen from the outside to the light-emitting device 502.

In some embodiments of this disclosure, the encapsulation can be achieved by thin-film encapsulation (TFE). Specifically, the encapsulation layer 600 can include a first inorganic layer, an organic layer, and a second inorganic layer. The first inorganic layer covers the surface of the second electrode layer away from the substrate 100. The organic layer can be disposed on the surface of the first inorganic layer away from the substrate 100, and the boundary of the organic layer is limited inside the boundary of the first inorganic layer. The second inorganic layer covers the organic layer and the part of the first inorganic layer not covered by the organic layer. Water and oxygen can be blocked by the second inorganic layer. Planarization can be achieved by the flexible organic layer.

The display panel further includes a shielding layer 201 and a buffer layer 202. The shielding layer 201 and the buffer layer 202 are disposed between the substrate 100 and the active layer 203, and the buffer layer 202 is disposed on the side of the shielding layer 201 away from the substrate 100.

In some embodiments of this disclosure, the display panel further includes a first gate insulating layer 204, a first gate metal layer 205, a second gate insulating layer 206, a second gate metal layer 207, an inter-layer dielectric layer 208, a first source-drain metal layer 209, a first planarization layer 211, a second source-drain metal layer 212, and a second planarization layer 213. The first gate insulating layer 204 is disposed on a side of the active layer 203 away from the substrate 100. The first gate metal layer 205 is disposed on a side of the first gate insulating layer 204 away from the substrate 100. The first gate metal layer 205 includes the gate of the target transistor, and the region of the active portion of the target transistor that overlaps with the gate of the target transistor in a direction perpendicular to the substrate 100 is the channel region. The second gate insulating layer 206 is disposed on a side of the first gate metal layer 205 away from the substrate 100. The second gate metal layer 207 is disposed on a side of the second gate insulating layer 206 away from the substrate 100. The inter-layer dielectric layer 208 is disposed on a side of the second gate metal layer 207 away from the substrate 100. The first source-drain metal layer 209 is disposed on a side of the inter-layer dielectric layer 208 away from the substrate 100. The first source-drain metal layer 209 includes the source and drain of the target transistor, and the active portion of the target transistor can include the channel region and the region used to connect to the source and drain of the transistor. The first planarization layer 211 is disposed on a side of the first source-drain metal layer 209 away from the substrate 100. The second source-drain metal layer 212 is disposed on a side of the first planarization layer 211 away from the substrate 100. The second planarization layer 213 is disposed on a side of the second source-drain metal layer 212 away from the substrate 100. The first metal layer 500 is disposed on a side of the second planarization layer 213 away from the substrate 100.

The plurality of metal layers further include the first gate metal layer 205, the second gate metal layer 207, the first source-drain metal layer 209, and the second source-drain metal layer 212.

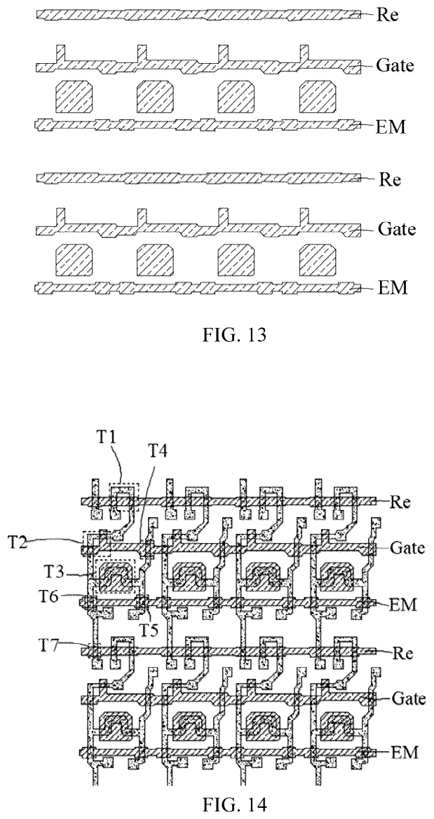

FIG. 13 of this disclosure exemplarily shows the layout of the first gate metal layer 205. The first gate metal layer 205 can include a reset signal line Re, an enable signal line EM, a gate driving signal line Gate, etc. The overlapping pattern of the first gate metal layer 205 and the active layer 203 is shown in FIG. 14. The overlapping region can be the channel regions corresponding to different transistors.

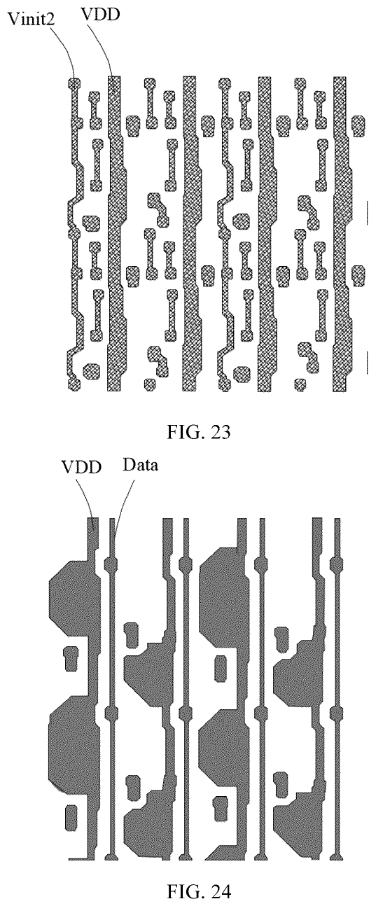

FIG. 22 exemplarily shows the layout of the second gate metal layer 207. The second gate metal layer 207 includes an initial signal line, and the initial signal line can include a first initial signal line Vinit1 and a second initial signal line Vinit2, which are used to provide the initial signal terminals in FIG. 1.

FIG. 23 exemplarily shows the layout of the first source-drain metal layer 209. The first source-drain metal layer 209 includes an initial signal line, such as the second initial signal line Vinit2, which is used to provide the initial signal terminal in FIG. 1. The first source-drain metal layer 209 also includes a first power supply voltage line VDD.

FIG. 24 exemplarily shows the layout of the second source-drain metal layer 212. The second source-drain metal layer 212 includes a first power supply voltage line VDD and a data line Data.

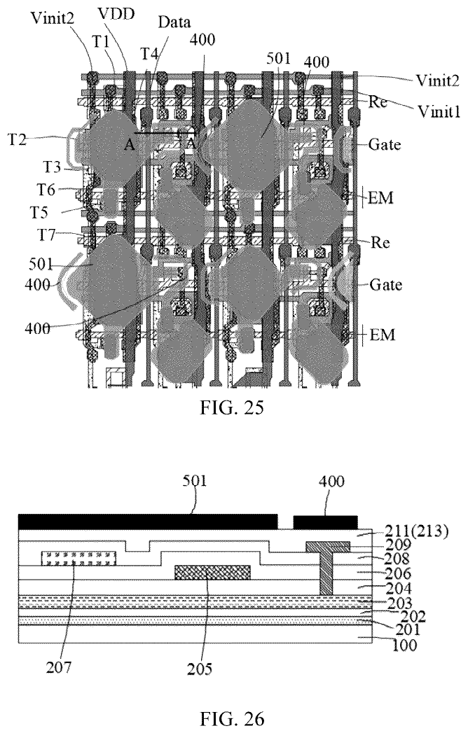

FIG. 25 exemplarily shows the superimposition schematic diagram of the layouts of FIGS. 12, 13, 22, 23, 24, and 15. FIG. 26 is a cross-sectional view at the position A-A in FIG. 25. The above only explains the signal lines in each metal layer. Each signal line can be connected through a conductor connection part according to the equivalent circuit diagram in FIG. 1, and there can be various connection methods, which are not limited here. And each metal layer can also contain other structures, which are not particularly limited in this disclosure.

A plurality of light-shielding portions 400 are distributed in at least one metal layer of the plurality of metal layers. That is, the light-shielding portions 400 can be distributed in at least one of the first gate metal layer 205, the second gate metal layer 207, the first source-drain metal layer 209, the second source-drain metal layer 212, and the first metal layer 500. The orthographic projection of the light-shielding portion 400 on the substrate 100 is separated from the orthographic projection of the first metal block 501 on the substrate 100. Further, the orthographic projection of the light-shielding portion 400 on the substrate 100 can surround the orthographic projection of the first metal block 501 on the substrate 100.

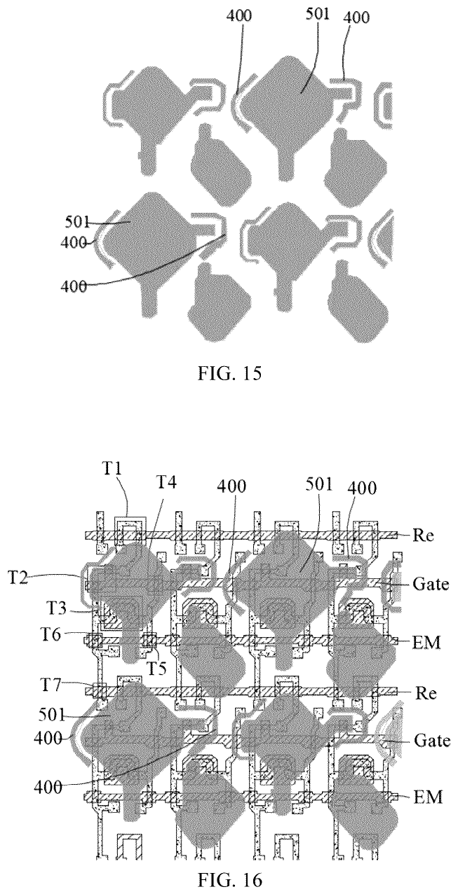

As shown in FIGS. 15-17, the first metal block 501 has a plurality of edges, the plurality of edges of the first metal block 501 are connected end to end, and the plurality of edges of the first metal block 501 include at least one target edge. The number of target edges can be one, two, or more. The orthographic projection of the target channel region 10 of the target transistor on the substrate 100 is located within the orthographic projection of the corresponding first metal block 501 on the substrate 100. FIG. 16 of this disclosure exemplarily shows the overlapping pattern of the active layer 203, the first gate metal layer 205, and the first metal layer 500. To clearly show the positional relationship between the channel region of the transistor and the first metal layer 500, other film layers are not shown in FIG. 15.

The distance, between the target channel region 10 of the target transistor and the target edge of the corresponding first metal block 501, in a direction parallel to the substrate 100, is not greater than, such as less than or equal to, the distance between the target channel region 10 of the target transistor and the other edge of the first metal block 501 in the direction parallel to the substrate 100. The target edges corresponding to the target channel regions 10 of different target transistors can be the same or different. One target channel region 10 of a target transistor can correspond to one, two, or more target edges. One target edge can also correspond to one, two, or more target channel regions 10 of target transistors. In some embodiments, the distance between the target channel region 10 and the target edge in the direction parallel to the substrate 100 is not greater than 5 μm, such as 4 μm, 3 μm, or 1 μm.

At least one light-shielding portion 400 is located at the position of the target edge. For example, a distance, between the target edge and at least one light-shielding portion 400, is greater than or equal to Oum. In some embodiments, the orthographic projection of the target channel region 10 of the target transistor on the first metal block 501 is a first projection, and the orthographic projection of the first projection on the target edge of the first metal block 501 is a second projection; the orthographic projection of the light-shielding portion 400 on the first metal layer 500 is a third projection, and the projection of the third projection on the target edge of the first metal block 501 is a fourth projection. The second projection is located within the fourth projection.

In this disclosure, the size of the light-shielding portion 400 can be set according to the amount of light required to be blocked for the target channel region 10 of the target transistor under wide-angle illumination. The amount of light required to be blocked for the target channel region 10 of the target transistor can be determined by the projection of the light-shielding portion 400 on the target channel region 10 under wide-angle light incidence. For example, if the light-shielding portions 400 are distributed in the first metal layer 500, the cross-sectional area of the target channel region 10 of the target transistor in a direction parallel to the substrate 100 is A, and the projected area of the light-shielding portion 400 on the target channel region 10 under wide-angle light incidence is B, the proportion of B in A can be determined according to the amount of light required to be blocked for the target channel region 10, and then the size of the light-shielding portion 400 can also be determined. Specifically, the proportion of B in A can be not less than 30%. The wide-angle light incidence can refer to the angle between the light and the display surface of the display panel. This angle can range from 20° to 80°, and of course, it can also be other angles, which are not particularly limited.

In this disclosure, the shape of the light-shielding portion 400 can be set according to the shape of the first metal block 501 surrounded and the position of the target channel region 10.

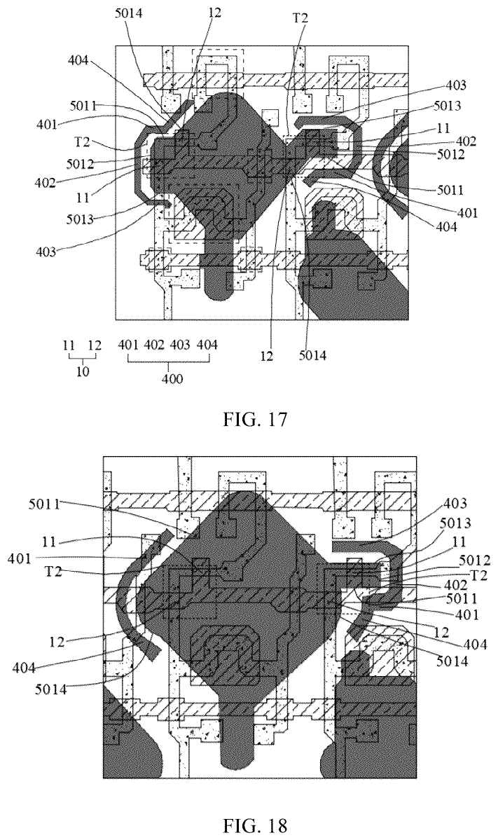

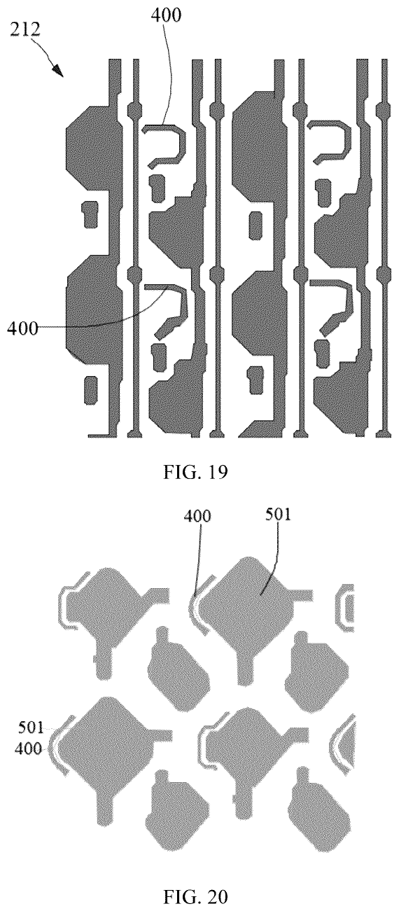

As shown in FIGS. 17 and 18, in some embodiments of this disclosure, the at least one target channel region 10 includes a first target channel region 11; the at least one target edge includes a first target edge 5011; the distance, between the first target channel region 11 of the target transistor and the first target edge 5011 of the corresponding first metal block 501, in the direction parallel to the substrate 100, is less than the distance between the first target channel region 11 of the target transistor and the other edge of the corresponding first metal block 501 except the target edge in the direction parallel to the substrate 100. The light-shielding portion 400 includes a first light-shielding portion 401, and the first light-shielding portion 401 is located on a side of the first target edge 5011 away from the first target channel region 11 in the direction parallel to the substrate 100. Further, the second projection of the first target channel region 11 of the target transistor on the first target edge 5011 is located within the fourth projection of the first light-shielding portion 401 on the first target edge 5011.

In some embodiments, the at least one target edge further includes a second target edge 5012. The first target edge 5011 and the second target edge 5012 are connected, and the first target edge 5011 and the second target edge 5012 have an included angle. This included angle can be greater than 0° and less than 180°. The distance, between the first target channel region 11 of the target transistor and the second target edge 5012 of the corresponding first metal block 501, in the direction parallel to the substrate 100, is less than the distance between the first target channel region 11 of the target transistor and the other edge of the corresponding first metal block 501 except the target edge in the direction parallel to the substrate 100. The light-shielding portion 400 further includes a second light-shielding portion 402. The second light-shielding portion 402 is located on a side of the second target edge 5012 away from the first target channel region 11 in the direction parallel to the substrate 100, and the second light-shielding portion 402 is connected to the first light-shielding portion 401. Further, the second projection of the first target channel region 11 of the target transistor on the second target edge 5012 is located within the fourth projection of the second light-shielding portion 402 on the second target edge 5012. The first light-shielding portion 401 and the second light-shielding portion 402 also have a certain included angle, and this included angle can be substantially equal to the included angle between the first target edge 5011 and the second target edge 5012.

In this embodiment, the first light-shielding portion 401 and the second light-shielding portion 402 are equivalent to surrounding the first target channel region 11 in two directions, which, to a certain extent, can increase the amount of light blocked from reaching the first target channel region 11.

In some embodiments of this disclosure, the at least one target edge can also include a third, fourth, fifth, or more target edges. For example, the at least one target edge further includes a third target edge 5013. The first target edge 5011, the second target edge 5012, and the third target edge 5013 are connected in sequence, and the second target edge 5012 and the third target edge 5013 have an included angle. This included angle can be greater than 0° and less than 180°. The distance, between the first target channel region 11 of the target transistor and the third target edge 5013 of the corresponding first metal block 501, in the direction parallel to the substrate 100, is less than the distance between the first target channel region 11 of the target transistor and the other edge of the corresponding first metal block 501 except the target edge in the direction parallel to the substrate 100. The light-shielding portion 400 further includes a third light-shielding portion 403. The third light-shielding portion 403 is located on a side of the third target edge 5013 away from the first target channel region 11 in the direction parallel to the substrate 100. The first light-shielding portion 401, the second light-shielding portion 402, and the third light-shielding portion 403 are connected in sequence. Further, the second projection of the first target channel region 11 of the target transistor on the third target edge 5013 is located within the fourth projection of the third light-shielding portion 403 on the third target edge 5013. The connection angles of the first light-shielding portion 401, the second light-shielding portion 402, and the third light-shielding portion 403 can be set according to the connection angles of the first target edge 5011, the second target edge 5012, and the second target edge 5012, and can be substantially equal to the connection angles of the first target edge 5011, the second target edge 5012, and the third target edge 5013.

In some embodiments of this disclosure, the number of target channel regions 10 is multiple. The at least one target channel region 10 further includes a second target channel region 12; the at least one target edge further includes a fourth target edge 5014. The fourth target edge 5014 is connected to the first target edge 5011, and the fourth target edge 5014 and the first target edge 5011 have an included angle. This included angle can be greater than 0° and less than 180°. The distance, between the second target channel region 12 of the target transistor and the fourth target edge 5014 of the corresponding first metal block 501, in the direction parallel to the substrate 100 is less than the distance between the second target channel region 12 of the target transistor and the other edge of the corresponding first metal block 501 except the target edge in the direction parallel to the substrate 100. The light-shielding portion 400 further includes a fourth light-shielding portion 404. The fourth light-shielding portion 404 is located on a side of the fourth target edge 5014 away from the second target channel region 12 in the direction parallel to the substrate 100, and the fourth light-shielding portion 404 is connected to the first light-shielding portion 401. The second projection of the second target channel region 12 of the target transistor on the fourth target edge 5014 is located within the fourth projection of the fourth light-shielding portion 404 on the fourth target edge 5014. In this embodiment, the target transistor can be a dual-channel transistor.

It should be noted here that for the second target channel region 12, the at least one target edge can also include a fifth target edge, a sixth target edge, etc. The setting of the fourth target edge 5014, the fifth target edge, and the sixth target edge can refer to the setting method of the first target edge 5011, the second target edge 5012, and the third target edge 5013 in the first target channel region 11, which will not be described in detail here.

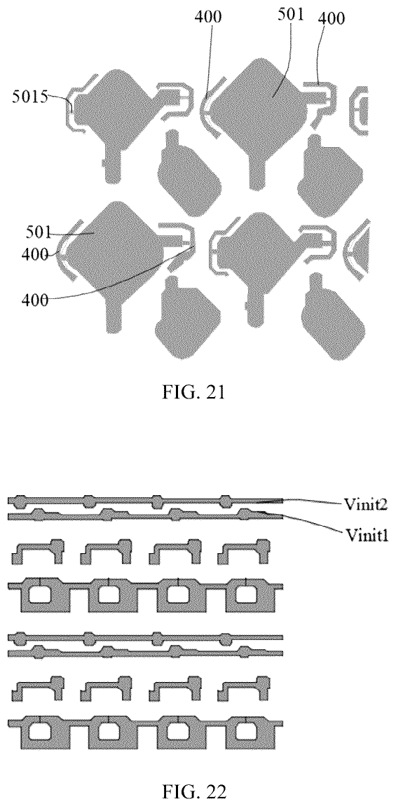

In some embodiments of this disclosure, the distance, between the orthographic projection of the light-shielding portion 400 on the substrate 100 and the orthographic projection of the first metal block 501 surrounded by the light-shielding portion on the substrate 100, ranges from Oum to 5 μm. When the light-shielding portion 400 is distributed in the first metal layer 500, the light-shielding portion 400 can be connected to the corresponding surrounded first metal block 501 to form an integral body. In this case, the distance between the orthographic projection of the light-shielding portion 400 on the substrate 100 and the orthographic projection of the first metal block 501 surrounded by the light-shielding portion on the substrate 100 is 0. Of course, when the light-shielding portion 400 is distributed in the first metal layer 500, the distance, between the light-shielding portion 400 distributed in the first metal layer 500 and the first metal block 501 surrounded by the light-shielding portion, ranges from 2 μm to 5 μm. In this way, it is helpful to reduce the problem of the decrease in the aperture ratio caused by the expansion of the first metal block 501 to form the light-shielding portion 400. Further, a connection portion 5015 is connected between the light-shielding portion 400 and the first metal block 501 surrounded by the light-shielding portion, and the connection portion 5015 is distributed in the first metal layer 500, as specifically shown in FIG. 21.

In some embodiments of this disclosure, the orthographic projection of the light-shielding portion 400 on the substrate 100 is a bent strip-shaped structure, and the width of the bent strip-shaped structure ranges from 2 μm to 5 μm. The light-shielding portion 400 is substantially a bent metal strip surrounding the first metal block 501, and the width of this metal strip in a direction parallel to the substrate 100 ranges from 2 μm to 5 μm.

In the embodiments shown in FIGS. 15-18, the target transistor is the second transistor T2. In addition, the target transistor can also be the first transistor T1. As shown in FIG. 28, the light-shielding portion 400 is disposed at the position of the first transistor T1.

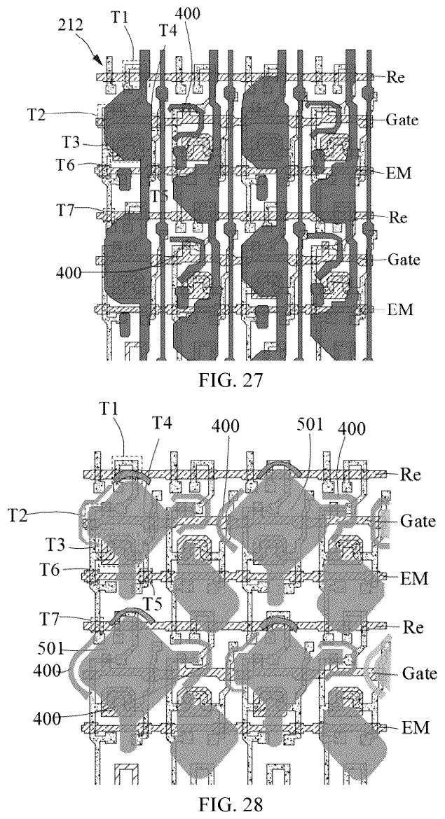

It should be noted here that FIGS. 15-18 exemplarily show the scheme in which the light-shielding portion 400 is distributed in the first metal layer 500. In addition, the light-shielding portion 400 can also be distributed in the first gate metal layer 205, the second gate metal layer 207, the first source-drain metal layer 209, and the second source-drain metal layer 212. For example, in an embodiment, some of the light-shielding portions 400 are distributed in the second source-drain metal layer 212, as shown in FIG. 19, and some of the light-shielding portions 400 are distributed in the first metal layer 500, as shown in FIG. 20. FIG. 27 exemplarily show a superimposition layout of the active layer 201, the first gate metal layer 205, and the second source-drain metal layer 212 is shown. It can be seen from the figure that the light-shielding portion 400 can at least partially block the target channel region of the second transistor T2.

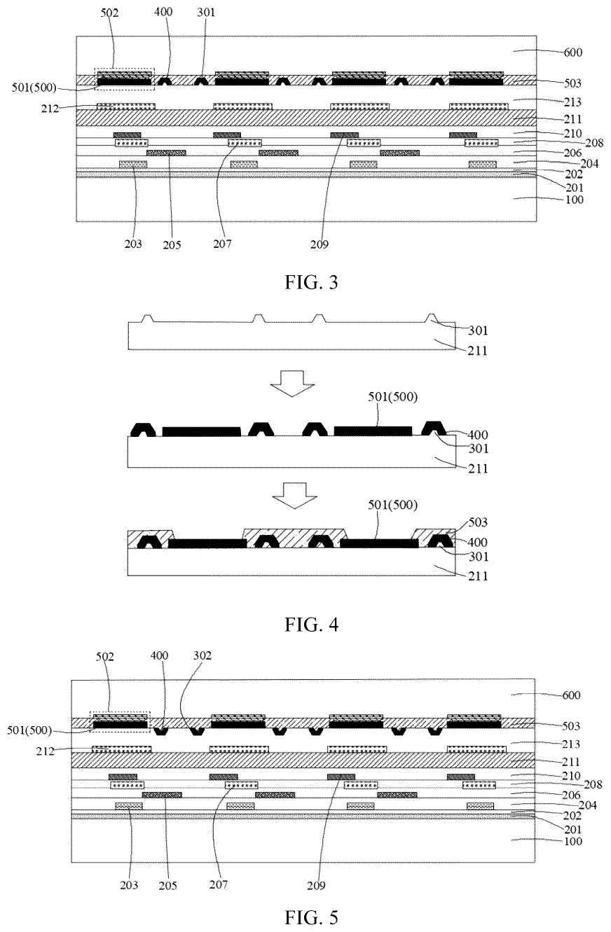

As shown in FIGS. 3-11, further, in order to reduce the problem of the decrease in the aperture ratio caused by the setting of the light-shielding portion 400, the display panel of this disclosure further includes a first insulating layer disposed on a side of the active layer 203 away from the substrate 100. The light-shielding portion 400 is disposed on a surface of the first insulating layer on a side away from the substrate 100. The surface of the first insulating layer on the side away from the substrate 100 is provided with a plurality of protrusions 301 or grooves 302. The light-shielding portion 400 at least covers the surface of the protrusion 301 or the groove 302.

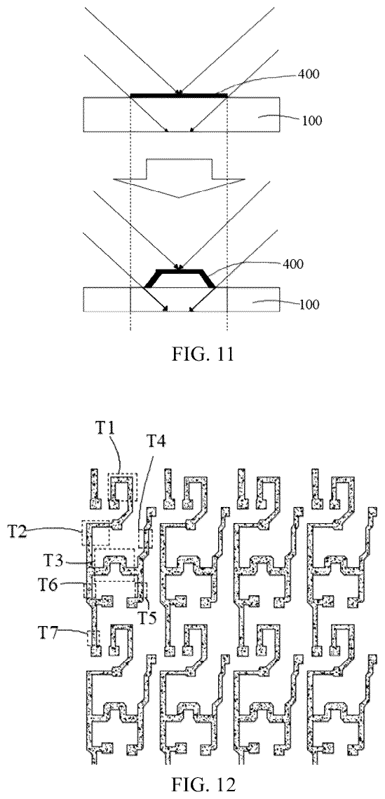

As shown in FIG. 11, when the protrusion 301 is provided on the first insulating layer, in the case of blocking the same amount of light, the projected area of the light-shielding portion 400 on the substrate 100 will be reduced compared with the scheme where the surface of the first insulating layer is flat, which is helpful to reduce the problem of the decrease in the aperture ratio caused by the setting of the light-shielding portion 400. Similarly, when the groove 302 is provided on the first insulating layer, it is also helpful to reduce the problem of the decrease in the aperture ratio caused by the setting of the light-shielding portion 400.

As shown in FIGS. 3 and 5-10, in this disclosure, the position of the first insulating layer in the film layers of the display panel can change with the distribution position of the light-shielding portion 400 in the plurality of metal layers. When the light-shielding portion 400 is distributed in the first gate metal layer 205, the first insulating layer is the first gate insulating layer 204. When the light-shielding portion 400 is distributed in the second gate metal layer 207, the first insulating layer is the second gate insulating layer 206. When the light-shielding portion 400 is distributed in the first source-drain metal layer 209, the first insulating layer is the inter-layer dielectric layer 208. When the light-shielding portion 400 is distributed in the second source-drain metal layer 212, the first insulating layer is the first planarization layer 211. When the light-shielding portion 400 is distributed in the first metal layer 500, the first insulating layer is the second planarization layer 213.

In this disclosure, the orthographic projection of the protrusion 301 or the groove 302 on the substrate 100 is located within the orthographic projection of the light-shielding portion 400 on the substrate 100. The cross-sectional shape of the protrusion 301 or the groove 302 in a direction perpendicular to the substrate 100 can be various. The following will describe the shapes of the protrusion 301 or the groove 302 in detail with reference to the accompanying drawings and specific embodiments.

As shown in FIGS. 3, 4, 6, and 8, in an embodiment of this disclosure, the surface of the first insulating layer on a side away from the substrate 100 is provided with a plurality of protrusions 301. The protrusion 301 has a bottom end close to the substrate 100, a top end away from the substrate 100, and a side wall connecting the bottom end and the top end. The orthographic projection of the top end of the protrusion 301 on the substrate 100 is located within the orthographic projection of the bottom end of the protrusion 301 on the substrate 100. In a direction perpendicular to the substrate 100, the cross-section of the protrusion 301 can be a regular trapezoid, an arc, or a triangle, etc. Further, the angle between the side wall of the protrusion 301 and the plane where the substrate 100 is located ranges from 25° to 70°.

For example, as shown in FIGS. 3 and 4, in a specific embodiment, the cross-section of the protrusion 301 in a direction perpendicular to the substrate 100 is a regular trapezoid. The angle between the side wall of this protrusion 301 and the plane where the substrate 100 is located ranges from 25° to 70°, preferably 45°. The bottom width of the cross-section of the protrusion 301 in the direction perpendicular to the substrate 100 ranges from 2 μm to 5 μm. The top width of the cross-section of the protrusion 301 in the direction perpendicular to the substrate 100 is less than the bottom width and can range from 0.5 μm to 4.5 μm. In this embodiment, the process for preparing the protrusion 301 and the light-shielding portion 400 is as shown in FIG. 4. An etching process can be used to form the protrusion 301 on the surface of the first insulating layer on the side of away from the substrate 100, and then the first metal layer 500 is deposited to form the first metal layer 500 containing the light-shielding portion 400.

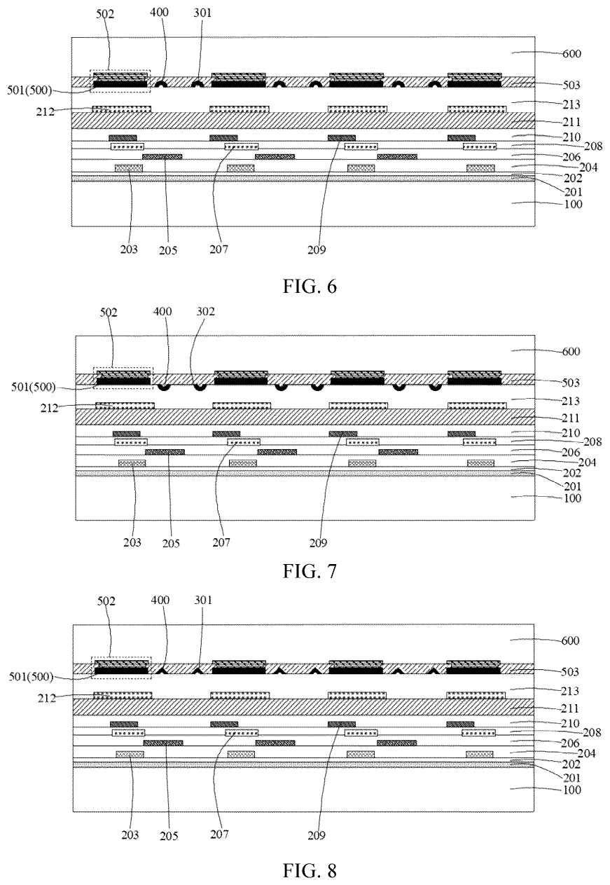

As shown in FIG. 6, in another specific embodiment, the cross-section of the protrusion 301 in a direction perpendicular to the substrate 100 is an arc. The length of the arc of this arc-shaped protrusion 301 can be less than the length of a semi-arc. The angle, between the tangent plane of the point on the side wall of the protrusion 301 and the plane where the substrate 100 is located, ranges from 0° to 70°, preferably 45°. The bottom width of the cross-section of the protrusion 301 in the direction perpendicular to the substrate 100 ranges from 2 μm to 5 μm.

As shown in FIG. 8, in yet another specific embodiment, the cross-section of the protrusion 301 in the direction perpendicular to the substrate 100 is a triangle. One end of this triangle away from the substrate 100 is a vertex, and the end close to the substrate 100 is a base. The angle, between the side wall of this protrusion 301 and the plane where the substrate 100 is located, ranges from 20° to 70°, preferably 45°. The bottom width of the cross-section of the protrusion 301 in the direction perpendicular to the substrate 100 ranges from 2 μm to 5 μm, that is, the length of the base of the triangle ranges from 2 μm to 5 μm.

As shown in FIGS. 5, 7, and 9, in some other embodiments of this disclosure, the surface of the first insulating layer away from the substrate 100 is provided with a plurality of grooves 302. The groove 302 has a bottom end close to the substrate 100, a top end away from the substrate 100, and a side wall connecting the bottom end and the top end. The orthographic projection of the bottom end of the groove 302 on the substrate 100 is located within the orthographic projection of the top end of the groove 302 on the substrate 100. In a direction perpendicular to the substrate 100, the cross-section of the groove 302 can be an inverted trapezoid, an arc, or a triangle, etc. Further, the angle, between the side wall of the groove 302 and the plane where the substrate 100 is located, ranges from 25° to 70°.

As shown in FIG. 5, for example, in a specific embodiment, the cross-section of the groove 302 in a direction perpendicular to the substrate 100 is an inverted trapezoid. The angle, between the side wall of this groove 302 and the plane where the substrate 100 is located, ranges from 25° to 70°, preferably 45°. The top width of the cross-section of the groove 302 in a direction perpendicular to the substrate 100 ranges from 2 μm to 5 μm. The bottom width of the cross-section of the groove 302 in a direction perpendicular to the substrate 100 is less than the top width and can range from 0.5 μm to 4.5 μm.

As shown in FIG. 7, in another specific embodiment, the cross-section of the groove 302 in a direction perpendicular to the substrate 100 is an arc. The length of the arc of this arc-shaped groove 302 can be less than the length of a semi-arc. The angle, between the tangent plane of the point on the side wall of the groove 302 and the plane where the substrate 100 is located, ranges from 0° to 70°, preferably 45°. The top width of the cross-section of the groove 302 in a direction perpendicular to the substrate 100 ranges from 2 μm to 5 μm.

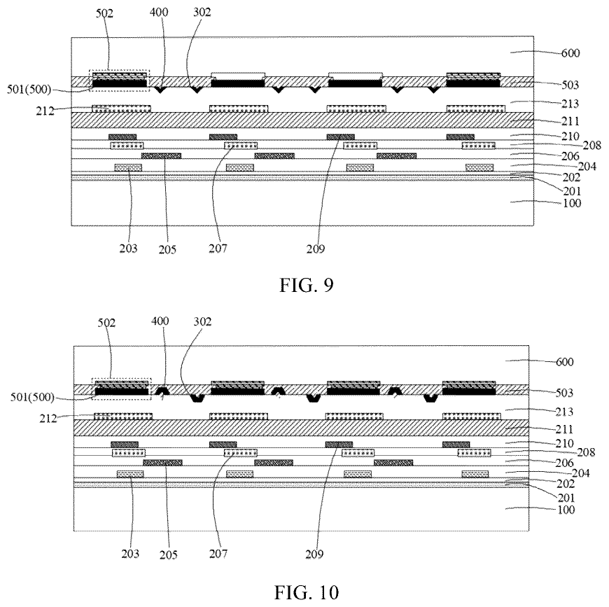

As shown in FIG. 9, in yet another specific embodiment, the cross-section of the groove 302 in a direction perpendicular to the substrate 100 is a triangle. One end of this triangle close to the substrate 100 is a vertex, and the end away from the substrate 100 is a top side. The angle, between the side wall of this groove 302 and the plane where the substrate 100 is located, ranges from 20° to 70°, preferably 45°. The top width of the cross-section of the groove 302 in a direction perpendicular to the substrate 100 ranges from 2 μm to 5 μm, that is, the length of the top side of the triangle ranges from 2 μm to 5 μm.

As shown in FIG. 10, in some other embodiments of this disclosure, the surface of the first insulating layer away from the substrate 100 is provided with a plurality of grooves 302 and a plurality of protrusions 301. The shapes of the protrusions 301 and the grooves 302 can refer to any of the above-mentioned embodiments, and will not be elaborated in detail here.

In the above-mentioned embodiments, the first insulating layer can be the first gate insulating layer 204, the second gate insulating layer 206, the inter-layer dielectric layer 208, the first planarization layer 211, or the second planarization layer 213, etc. In the figures, the first insulating layer is exemplified as the second planarization layer 213.

The embodiment of this disclosure also provides a display device including a display panel. The display panel can be the display panel of any of the above-mentioned embodiments. Its specific structure and beneficial effects can refer to the embodiments of the display panel described above, and will not be repeated here. The display device of this disclosure can be a mobile phone, a tablet computer, a TV, and other electronic devices, which will not be listed one by one here.

It should be noted that although the steps of the methods in this disclosure are described in a specific order in the drawings, this does not require or imply that these steps must be executed in this specific order, or that all the shown steps must be executed to achieve the desired result. Additionally or alternatively, some steps can be omitted, multiple steps can be combined into one step for execution, and/or one step can be decomposed into multiple steps for execution, etc., all of which should be regarded as part of this disclosure.

It should be understood that this disclosure does not limit its application to the detailed structure and arrangement of components set forth in this specification. This disclosure can have other embodiments and can be implemented and executed in various ways. The variations and modifications of the embodiments fall within the scope of this disclosure. It should be understood that the disclosure and definition of this disclosure in this specification extend to all alternative combinations of two or more individual features mentioned or apparent in the text and/or the drawings. All these different combinations constitute multiple alternative aspects of this disclosure. The embodiments of this specification illustrate some ways known for implementing this disclosure and will enable those skilled in the art to utilize this disclosure.

What is claimed is:

1. A display panel, comprising:
a pixel circuit comprising at least one target transistor;
a substrate;
an active layer, on a side of the substrate, comprising an active portion of the target transistor, the active portion of the target transistor comprising a channel region, the channel region of the target transistor comprising at least one target channel region;
a plurality of metal layers, on a side of the active layer away from the substrate, comprising a first metal layer, the first metal layer comprising a plurality of independent first metal blocks; and
a plurality of light-shielding portions distributed in at least one metal layer of the plurality of metal layers, an orthographic projection of the light-shielding portion on the substrate being separated from an orthographic projection of the first metal block on the substrate; wherein
the first metal block has a plurality of edges connected end to end, the plurality of edges of the first metal block comprising at least one target edge;
an orthographic projection of the active portion of the target transistor on the substrate at least partially overlaps with an orthographic projection of the corresponding first metal block on the substrate;
a distance, between the target channel region of the target transistor and the target edge of the corresponding first metal block, in a direction parallel to the substrate, is less than or equal to a distance, between the target channel region of the target transistor and an other edge of the corresponding first metal block, in the direction parallel to the substrate; and
a distance, between the target edge and at least one of the plurality of light-shielding portions, is greater than or equal to 0 μm.

2. The display panel according to claim 1, wherein an-the orthographic projection of the light-shielding portion on the substrate surrounds the orthographic projection of the first metal block on the substrate; and
a distance, between the orthographic projection of the light-shielding portion on the substrate and the orthographic projection of the first metal block surrounded by the light-shielding portion on the substrate, ranges from 0 μm to 5 μm.

3. The display panel according to claim 1, wherein an orthographic projection of the target channel region of the target transistor on the corresponding first metal block is a first projection, and an orthographic projection of the first projection on the target edge of the corresponding first metal block is a second projection; and
an orthographic projection of the light-shielding portion on the first metal layer is a third projection, and a projection of the third projection on the target edge of the corresponding first metal block is a fourth projection, the second projection being located within the fourth projection.

4. The display panel according to claim 1, further comprising:
a first insulating layer on a side of the active layer away from the substrate, the light-shielding portion being on a surface of the first insulating layer on a side away from the substrate;
wherein the surface of the first insulating layer on the side away from the substrate is provided with a plurality of protrusions or grooves, and the light-shielding portion at least covers a surface of the protrusion or the groove; and
wherein a height of the protrusion ranges from 0.5 μm to 2 μm; and a depth of the groove ranges from 0.5 μm to 2 μm.

5. The display panel according to claim 4, wherein the protrusion has a bottom end close to the substrate, a top end away from the substrate, and a side wall connecting the bottom end and the top end, and an orthographic projection of the top end of the protrusion on the substrate is located within an orthographic projection of the bottom end of the protrusion on the substrate; and
wherein an angle, between the side wall of the protrusion and a plane where the substrate is located, ranges from 25° to 70°.

6. (canceled)

7. The display panel according to claim 54, wherein the groove has a bottom end close to the substrate, a top end away from the substrate, and a side wall connecting the bottom end and the top end, and an orthographic projection of the bottom end of the groove on the substrate is located within an orthographic projection of the top end of the groove on the substrate; and
wherein an angle, between the side wall of the groove and a plane where the substrate is located, ranges from 25° to 70°.

8. (canceled)

9. (canceled)

10. The display panel according to claim 4, further comprising:
a first gate insulating layer on the side of the active layer away from the substrate;
a first gate metal layer, on a side of the first gate insulating layer away from the substrate, comprising a gate of the target transistor;
a second gate insulating layer on a side of the first gate metal layer away from the substrate;
a second gate metal layer on a side of the second gate insulating layer away from the substrate;
an inter-layer dielectric layer on a side of the second gate metal layer away from the substrate;
a first source-drain metal layer, on a side of the inter-layer dielectric layer away from the substrate, comprising a source and a drain of the target transistor;
a first planarization layer on a side of the first source-drain metal layer away from the substrate;
a second source-drain metal layer on a side of the first planarization layer away from the substrate; and
a second planarization layer on a side of the second source-drain metal layer away from the substrate, wherein the first metal layer is on a side of the second planarization layer away from the substrate;
wherein the plurality of metal layers further comprise the first gate metal layer, the second gate metal layer, the first source-drain metal layer, and the second source-drain metal layer;
when the plurality of light-shielding portions are distributed in the first gate metal layer, the first gate insulating layer serves are the first insulating layer;
when the plurality of light-shielding portions are distributed in the second gate metal layer, the second gate insulating layer serves as the first insulating layer;
when the plurality of light-shielding portions are distributed in the first source-drain metal layer, the inter-layer dielectric layer serves as the first insulating layer;
when the plurality of light-shielding portions are distributed in the second source-drain metal layer, the first planarization layer serves as the first insulating layer;
when the plurality of light-shielding portion are distributed in the first metal layer, the second planarization layer serves as the first insulating layer.

11. The display panel according to claim 1, wherein the at least one target channel region comprises a first target channel region;
the at least one target edge comprises a first target edge;
a distance, between the first target channel region of the target transistor and the first target edge of the corresponding first metal block, in the direction parallel to the substrate, is less than a distance, between the first target channel region of the target transistor and an other edge of the corresponding first metal block except the target edge, in the direction parallel to the substrate; and
the plurality of light-shielding portions comprise a first light-shielding portion on a side, away from the first target channel region, of the first target edge in the direction parallel to the substrate.

12. The display panel according to claim 11, wherein the at least one target edge further comprises a second target edge connected to the first target edge, with an angle between the first target edge and the second target edge;
a distance, between the first target channel region of the target transistor and the second target edge of the corresponding first metal block, in the direction parallel to the substrate, is less than a distance, between the first target channel region of the target transistor and an other edge of the corresponding first metal block except the target edge, in the direction parallel to the substrate; and
the plurality of light-shielding portion further comprise a second light-shielding portion on a side, away from the first target channel region, of the second target edge in the direction parallel to the substrate, the second light-shielding portion being connected to the first light-shielding portion.

13. The display panel according to claim 12, wherein the at least one target edge further comprises a third target edge, with the first target edge, the second target edge, and the third target edge connected in sequence, and an angle between the second target edge and the third target edge;
a distance, between the first target channel region of the target transistor and the third target edge of the corresponding first metal block, in the direction parallel to the substrate, is less than a distance, between the first target channel region of the target transistor and an other edge of the corresponding first metal block except the target edge, in the direction parallel to the substrate;
and the plurality of light-shielding portions further comprise a third light-shielding portion on a side, away from the first target channel region, of the third target edge in the direction parallel to the substrate, the first light-shielding portion, the second light-shielding portion, and the third light-shielding portion being connected in sequence.

14. The display panel according to claim 11, wherein the at least one target channel region further comprises a second target channel region;
the at least one target edge further comprises a fourth target edge connected to the first target edge, with an angle between the fourth target edge and the first target edge;
a distance, between the second target channel region of the target transistor and the fourth target edge of the corresponding first metal block in the direction parallel to the substrate, is less than a distance, between the second target channel region of the target transistor and an other edge of the corresponding first metal block except the target edge, in the direction parallel to the substrate; and
the plurality of light-shielding portions further comprise a fourth light-shielding portion on a side, away from the second target channel region, of the fourth target edge in the direction parallel to the substrate, the fourth light-shielding portion being connected to the first light-shielding portion.

15. The display panel according to claim 1, wherein the orthographic projection of the light-shielding portion on the substrate is a bent strip-shaped structure, and a width of the bent strip-shaped structure ranges from 2 μm to 5 μm.

16. The display panel according to claim 1, further comprising:
a first source-drain metal layer, on the side of the active layer away from the substrate, comprising a source and a drain of the target transistor;
a first planarization layer on a side of the first source-drain metal layer away from the substrate;
a second source-drain metal layer on a side of the first planarization layer away from the substrate; and
a second planarization layer on a side of the second source-drain metal layer away from the substrate, wherein the first metal layer is on a side of the second planarization layer away from the substrate;
wherein the plurality of metal layers comprise the first source-drain metal layer, the second source-drain metal layer, and the first metal layer; and
at least a portion of the plurality of light-shielding portions are distributed in the first metal layer and/or the second source-drain metal layer.

17. The display panel according to claim 16, wherein the orthographic projection of the light-shielding portion on the substrate surrounds the orthographic projection of the first metal block on the substrate; and
a distance, between the light-shielding portion distributed in the first metal layer and the first metal block surrounded by the light-shielding portion, ranges from 2 μm to 5 μm.

18. The display panel according to claim 17, wherein a connection portion is connected between the light-shielding portion distributed in the first metal layer and the first metal block surrounded by the light-shielding portion, and the connection portion is distributed in the first metal layer.

19. The display panel according to claim 1, wherein a distance, between the target channel region and the target edge, in the direction parallel to the substrate, is less than or equal to 5 μm.

20. The display panel according to claim 1, wherein the pixel circuit comprises:
a driving transistor; and
a second transistor, a first electrode of the second transistor being connected to a first electrode of the driving transistor, a second electrode of the second transistor being connected to a gate of the driving transistor, and a gate of the second transistor being connected to a gate driving signal terminal; and
wherein the second transistor serves as the target transistor.

21. The display panel according to claim 20, wherein the second transistor is a dual-channel transistor.

22. The display panel according to claim 20, wherein the pixel circuit further comprises:
a first transistor, with a first electrode connected to a first node, a second electrode connected to an initial signal terminal, and a gate connected to a reset signal terminal;
a fourth transistor, a first electrode of the fourth transistor being connected to a data signal terminal, a second electrode of the fourth transistor being connected to a second electrode of the driving transistor, and a gate of the fourth transistor being connected to the gate driving signal terminal;
a fifth transistor, a first electrode of the fifth transistor being connected to a first power supply terminal, a second electrode of the fifth transistor being connected to the second electrode of the driving transistor, and a gate of the fifth transistor being connected to an enable signal terminal;
a sixth transistor, a first electrode of the sixth transistor being connected to the first electrode of the driving transistor, and a gate of the sixth transistor being connected to the enable signal terminal;
a seventh transistor, a first electrode of the seventh transistor being connected to the initial signal terminal, a second electrode of the seventh transistor being connected to a second electrode of the sixth transistor, and a gate of the seventh transistor being connected to the reset signal terminal; and
a capacitor connected between the gate of the driving transistor and the first power supply terminal;
wherein the first electrode of the second transistor is connected to the first electrode of the driving transistor, the second electrode of the second transistor is connected to the first node, the gate of the second transistor is connected to the gate driving signal terminal, and the gate of driving transistor is connected to the first node.

23. (canceled)

24. A display device, comprising the display panel according to claim 1.
